(19) United States
(12) Patent Application Publication
(10) Pub. No.: US 2013/0183535 A1
(43) Pub. Date: Jul. 18, 2013

(54) ADHESIVE COMPOSITION AND SEMICONDUCTOR DEVICE USING THE SAME

(71) Applicants: Kaoru Konno, Tsukuba-shi (JP); Hiroki Hayashi, Tsukuba-shi (JP)

(72) Inventors: Kaoru Konno, Tsukuba-shi (JP); Hiroki Hayashi, Tsukuba-shi (JP)

(21) Appl. No.: 13/823,278

(22) PCT Filed: Sep. 27, 2011
(86) PCT No.: PCT/JP2011/072043

§ 371 Date: Mar. 14, 2013

(30) Foreign Application Priority Data
Sep. 29, 2010 (JP) 2010-218721

(51) Int. Cl. H01L 23/00

(52) U.S. Cl. CPC H01L 24/83
USPC 428/457; 252/76; 252/74

(57) ABSTRACT

An adhesive composition having high electrical conductibility and thermal conductivity under no load and even at a curing temperature of 200° C. or lower, and having a high adhesive force even at 260° C., and a semiconductor device produced by using the adhesive composition are provided. Disclosed is an adhesive composition comprising (A) silver particles having a state ratio of oxygen derived from silver oxide of less than 15% as measured by X-ray photoelectron spectroscopy, and (B) an alcohol or carboxylic acid having a boiling point of 300° C. or higher.

### TECHNICAL FIELD

The present invention relates to an adhesive composition having excellent electrical conductivity, thermal conductivity, and adhesiveness. More particularly, the present invention relates to an adhesive composition which is suitable for adhering semiconductor elements such as IC, LSI and light emission diodes (LED) to substrates such as lead frames, ceramic wiring boards, glass epoxy wiring boards, and polyimide wiring boards, and to a semiconductor device using this adhesive composition.

### BACKGROUND ART

In the production of semiconductor devices, for adhering a semiconductor element to a lead frame (supporting member), there may be a method that uses a paste form (for example, a silver paste) prepared by dispersing a filler such as a silver powder in a resin such as an epoxy-based resin or a polyimide-based resin, as an adhesive. In this method, a paste-like adhesive is applied on a die pad of a lead frame by using a dispenser, a printing machine, a stamping machine or the like, subsequently a semiconductor element is die-bonded thereto, and the semiconductor element is adhered to the lead frame by heating and curing to thereby obtain a semiconductor device.

This semiconductor device is further subjected to semiconductor packaging by having the exterior encapsulated with an encapsulant, and then is mounted on a wiring board by soldering. Since the recent mounting technologies are required to provide higher density and higher efficiency, surface mounting methods of soldering the lead frame of a semiconductor device directly to a substrate, constitute the mainstream of solder mounting. In this surface mounting, a reflow soldering technique of heating a substrate as a whole by means of infrared radiation or the like is used, and the package is heated to a high temperature of 200° C. or higher. At this time, if moisture is present inside the package, particularly within an adhesive layer, this moisture is vaporized and moves around to enter between the die pad and the encapsulant, causing a crack (reflow crack) in the package. Since this reflow crack markedly decreases the reliability of semiconductor devices, the reflow crack gives rise to serious problems and technical problems. Thus, it has been requested to increase reliability, including adhesive force at high temperatures, of those adhesives that are frequently used in the adhesion of semiconductor elements and semiconductor supporting members.

Furthermore, in recent years, along with the increase in the processing speed and the progress of higher integration in semiconductor elements, high heat dissipation characteristics are requested in order to secure operational stability of semiconductor devices, in addition to the reliability such as adhesive force that has been traditionally sought for. That is, in order to solve the problems described above, there has been a demand for an adhesive composition having both high adhesive force and high thermal conductivity, which is to be used in the adhesive for bonding heat dissipation members and semiconductor elements.

Also, as a means for achieving superior heat dissipation properties than those of conventional electroconductive adhesives that are based on the contact between metal particles, there have been suggested a composition highly filled with silver particles having high thermal conductivity (Patent Documents 1 to 3), a composition using solder particles (Patent Document 4), a composition using metal nanoparticles with excellent sinterability having an average particle size of 0.1 μm or less (Patent Document 5), and an adhesive composition obtained by using micrometer-sized silver particles to which a special surface treatment has been applied, and sintering the metal microparticles at a temperature of approximately 200° C. (Patent Document 6).

Conventionally, as a method for securing high thermal conductibility of an adhesive, a method of densely filling the adhesive with silver particles having high thermal conductivity has been adopted. However, in order to secure a thermal conductivity of 20 W/m·K or greater that is required in power IC's and LED's of recent years, a very large amount of filling such as 95 parts by weight or more has been needed. However, when the amount of filling of silver particles increases, there is a problem that as viscosity also increases, threading or the like occurs at the time of dispensing, and workability may not be secured. Furthermore, if a large amount of a solvent is added so as to secure workability, void generation or a decrease in the adhesive force due to residual solvent causes a problem.

There is also a case of attempting an increase in thermal conductivity and a securement of strength at room temperature by means of formation of a thermal conduction path through metal bonding and metallization with an object to be adhered, by using a low melting point metal. However, when a PKG such as a power IC or an LED is mounted on a substrate, the mounted substrate is exposed to 260° C. in a reflow furnace, but there is a problem that bonded parts undergo remelting due to the thermal history, and reliability may not be obtained.

In order to avoid the problem of remelting of the bonded parts, an investigation on an electroconductive adhesive using metal nanoparticles is underway. However, a large expenditure is required to produce metal particles having a size in the order of nanometers, and a large amount of a surface protective material is needed to obtain dispersion stability of the metal nanoparticles. Thus, there are occasions in which a high temperature of 200° C. or higher is needed for sintering, or many process-related problems, such as that a sufficient adhesive force is not exhibited under no-load conditions.

In addition, it has been proposed that by subjecting silver particles to a particular surface treatment, when a predetermined thermal history is applied, sintering of the silver particles is promoted, and a solid silver having excellent electrical conductibility and thermal conductibility is obtained. However, the inventors of the present invention conducted an investigation, and as a result, when an adhesive composition composed of silver particles that have been subjected to the treatment for promoting sintering based on the invention described above and a volatile component, was used to bond a gold-plated silicon chip (size: 2 mm×2 mm) with a silver-plated copper lead frame by oven curing at 180° C. for one hour, there emerged a problem that the adhesive force to a gold plating interface is weak.

### CITATION LIST

### Patent Document

Patent Document 1: Japanese Patent Application Laid-Open No. 2006-73811
Patent Document 2: Japanese Patent Application Laid-Open No. 2006-302834
Patent Document 3: Japanese Patent Application Laid-Open No. 11-66953
Patent Document 4: Japanese Patent Application Laid-Open No. 2005-93996
Patent Document 5: Japanese Patent Application Laid-Open No. 2006-83377
Patent Document 6: Japanese Patent No. 4353380

### SUMMARY OF INVENTION

### Technical Problem

It is an object of the present invention to provide an adhesive composition which has high electrical conductibility and thermal conductivity even at a curing temperature of 200° C. or lower, maintains a high adhesive force even at 260° C., and exhibits sufficient adhesiveness even under no-load conditions, or a semiconductor device produced by using the adhesive composition.

### Solution to Problem

The present invention relates to the following items (1) to (6).

(1) An adhesive composition comprises: (A) silver particles having a state ratio of oxygen derived from silver oxide of less than 15% as measured by X-ray photoelectron spectroscopy; and (B) an alcohol or carboxylic acid having a boiling point of 300° C. or higher.

(2) The adhesive composition as described in (1) further comprises (C) a volatile component having a boiling point of 100° C. to 300° C.

(3) The adhesive composition as described in (1) or (2), wherein the silver particles are obtained by subjecting to: a treatment for removing oxide film until the silver particles have a state ratio of oxygen derived from silver oxide of less than 15% as measured by X-ray photoelectron spectroscopy, and; a surface treatment for preventing reoxidation and aggregation of the silver particles.

(4) In the adhesive composition as described in any one of (1) to (3), an average particle size of the silver particles is from 0.1 μm to 50 μm.

(5) In the adhesive composition as described in any one of (1) to (4), a volume resistivity is 1×10⁴ Ω·cm or less and a thermal conductivity is 30 W/m·K or higher when the silver particles are sintered by applying a thermal history of from 100° C. to 200° C.

(6) A semiconductor device has a structure in which a semiconductor element and a supporting member for mounting a semiconductor element are adhered by means of the adhesive composition as described in any one of (1) to (5).

### Advantageous Effects of Invention

According to the present invention, an adhesive composition that is used as an electronic component, an electroconductive bonding material, an electroconductive adhesive or a die-bonding material, which composition has high electrical conductibility and thermal conductibility even at a curing temperature of 200° C. or lower, maintains a high adhesive force even at a reflow temperature of 260° C., and exhibits sufficient adhesiveness even under no-load conditions, and an electronic component-mounted substrate and a semiconductor device using the adhesive composition can be provided.

The disclosure of the present invention relates to the subject matter included in Japanese Patent Application No. 2010-218721 (filing date: Sep. 29, 2010), the disclosure of which is incorporated herein by reference in its entirety.

### BRIEF DESCRIPTION OF DRAWINGS

FIG. 1 is a schematic diagram of silver particles with less oxide film.

FIG. 2 is a schematic diagram illustrating the state in which the surface protective material of the silver particles with less oxide film illustrated in FIG. 1 has been detached by heating, and the silver particles have been sintered to each other.

FIG. 3 is a schematic diagram of silver particles with much oxide film.

FIG. 4 is a schematic diagram illustrating the state in which the surface protective material of the silver particles with much oxide film illustrated in FIG. 3 has been detached by heating, and the silver particles cannot be sintered to each other.

FIG. 5 is a schematic diagram of silver particles obtained by removing the oxide film from the silver particles with much oxide film illustrated in FIG. 3, and subjecting the silver particles to a surface treatment by adsorbing a particular surface protective material to the silver particles.

FIG. 6 is a schematic diagram illustrating the state in which the particular surface protective material adsorbed on the silver particles that have been subjected to the removal of oxide film and the surface treatment as illustrated in FIG. 5, has been detached by heating, and the silver particles have been sintered to each other.

FIG. 7 is a diagram illustrating an example of a semiconductor device using the connection material of the present invention.

FIG. 8 is a diagram illustrating another example of a semiconductor device using the connection material of the present invention.

### DESCRIPTION OF EMBODIMENTS

In regard to the mechanism for enhancements of thermal conductibility and electrical conductibility according to the present invention, it is speculated that when a surface protective material is detached by heating, and silver particles with their active surface being exposed are brought into contact and bonded with each other, paths of metallic bonding are formed as a result of sintering of the silver particles, and enhancements of thermal conductibility and electrical conductibility are achieved. That is, conventionally, it has been thought that sinter requires heating to a temperature of 200° C. or higher, and therefore, particles having a size of 0.1 μm or less have superior sinterability. However, it is contemplated that if particles are designed such that the active surface of silver particles are exposed by heating or the like, sintering occurs at a heating temperature of 200° C. or lower, or even if the silver particle size is greater than 0.1 μm, paths of metallic bonding between the silver particles are formed, and thereby enhancements of thermal conductibility and electrical conductibility are achieved. The mechanism will be explained below with reference to schematic diagrams.

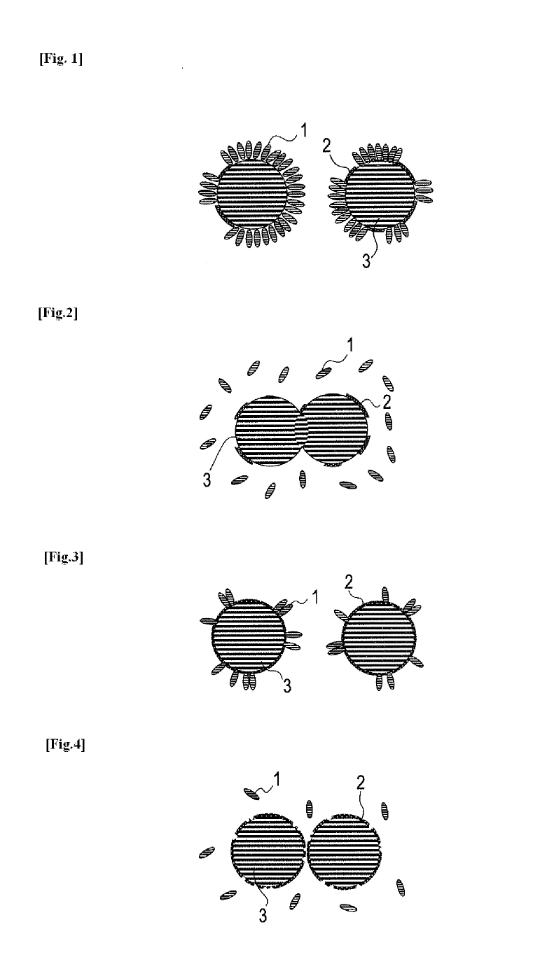

When an adhesive composition comprising silver particles (bulk metal) 3 with less oxide film 2 as illustrated in FIG. 1 is heated, a surface protective material 1 is detached from the silver particle surfaces as illustrated in FIG. 2, and active surfaces are exposed. It is contemplated that as these active surfaces are brought into contact, sintering is promoted.

Therefore, in the case of the silver particles with much oxide film 2 as illustrated in FIG. 3, it is speculated that since the oxide film 2 is covering a large area of the surface of the silver particles even after the detachment of the surface protective material 1 caused by heating as illustrated in FIG. 4, contact between the active surfaces does not easily occur, and sintering between the silver particles does not easily occur.

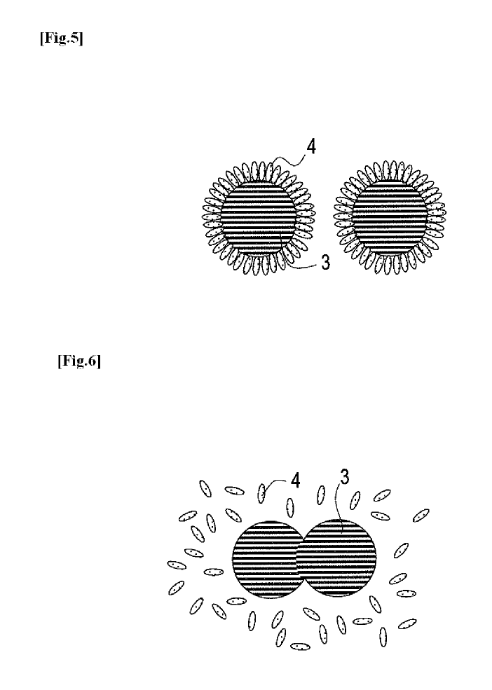

However, it is contemplated that even in the silver particles having much oxide film as illustrated in FIG. 3, when the oxide film is removed, and then the silver particles are subjected to a surface treatment using a particular surface protective material 4 for the prevention of reoxidation and the prevention of aggregation of the silver particles, silver particles without oxide film can be produced (FIG. 5). Furthermore, it is also contemplated that when an adhesive composition comprising silver particles that have been subjected to that treatment is heated, as illustrated in FIG. 6, silver particles can be sintered.

It was also found that the adhesive force is enhanced by an adhesive composition comprising an alcohol or carboxylic acid having a boiling point of 300° C. or higher. It is contemplated that when subjected to a thermal history, an alcohol or carboxylic acid having a high boiling point does not immediately volatilize, and a portion thereof remains, so that as the remaining alcohol or carboxylic acid removes the oxide film at the surface of the object to be adhered, the adhesive force to the object to be adhered is increased. Hereinafter, the details of the present invention will be described.

The adhesive composition according to the present invention comprises silver particles, and an alcohol or carboxylic acid having a boiling point of 300° C. or higher, as essential components. The details of the respective components will be described below.

It is essential that the silver particles used in the adhesive composition of the present invention have a state ratio of oxygen derived from silver oxide of less than 15%. When the amount of oxide film is 15% or greater, at a temperature equal to or lower than 200° C. or in an environment which lacks a reducing agent that accelerates the removal of oxide film, sintering between the silver particles is inhibited while the oxide film is covering a large area of the surface of the silver particles, and paths of metallic bonding between the silver particles are not sufficiently formed. Therefore, an adhesive composition using the silver particles tends to have lowered thermal conductivity. Meanwhile, the amount of the oxide film on the surface of the silver particles is based on the state ratio calculated from the data measured by X-ray photoelectron spectroscopy. As the analyzer for X-ray photoelectron spectroscopy, S-Probe ESCA Model 2803 manufactured by Surface Science Instruments, Inc. was used, and Al Kα radiation was used as the X-ray for irradiation. The oxygen derived from silver oxide was defined as a component having a peak at 531±1 eV, and was distinguished from oxygen derived from other components such as a surface protective agent. The state ratio is the concentration of a particular element in a sample for measurement, and is expressed as a value calculated from the intensity of the element by using the relative sensitivity coefficient of the analyzer.

The average particle size of the silver particles is not particularly limited, but the average particle size is preferably from 0.1 μm to 50 μm. When the production cost for the particles is considered, the average particle size is preferably 0.1 μm or greater, and when increasing of the filling ratio of the particles in order to enhance the thermal conductivity is considered, the average particle size is preferably 50 μm or less.

In the present invention, a silver particle surface treatment method of reducing or completely removing the amount of the oxide film of silver particles, and thereby preventing reoxidation and aggregation of the silver particles, was established. Through this treatment method, the state ratio of oxygen derived from silver oxide can be adjusted to less than 15%. The technique of the method will be described below.

First, silver particles are added to an acidic solution prepared by dissolving and dispersing a surface protective material, and while the mixture is stirred, removal of the oxide film and surface protection are carried out. The amount of addition of the silver particles relative to 100 parts by weight of the acidic solution is preferably 1 part to 50 parts by weight. Subsequently, the silver particles are removed by filtering the solution, and then the surface protective material or the acid component that has physically adsorbed to the surfaces of the silver particles is washed with a solvent. Thereafter, the silver particles are dried under reduced pressure to remove any excess solvent, and thus a surface-treated silver powder is obtained in a dried state. Furthermore, in the process of the removal of oxide film, when removal of the oxide film is carried out in an acidic solution which does not contain a surface protective material, it has been confirmed that the silver particles aggregate with each other, and silver particles in a powder form having an average particle size that is equal to that of the particles prior to the removal of oxide film are not obtained. Thus, in order to prevent the aggregation of silver particles, it is necessary to add a surface protective material in the acidic solution and to simultaneously carry out the removal of oxide film and the surface protection.

There are no limitations on the composition of the acidic solution, but as the acid, sulfuric acid, nitric acid, hydrochloric acid, acetic acid, phosphoric acid, or the like can be used. There are also no limitations on the diluting solvent for the acid, but a solvent which has satisfactory compatibility with the acid and has excellent dissolubility and dispersibility of the surface protective material is preferred.

As for the concentration of acid in the acidic solution, in order to remove the oxide film, when the total amount of the acidic solution is designated as 100 parts by weight, the concentration of acid is preferably 1 part by weight or greater, and in case that the silver particles have a thick oxide film, the concentration is more preferably 5 parts by weight or greater. Furthermore, if the concentration of acid is too high, a large amount of silver is dissolved into the solution. Therefore, the concentration of acid is preferably 50 parts by weight or less, and in order to prevent aggregation between the particles, the concentration is more preferably 40 parts by weight or less.

The surface protective material is preferably a compound having a terminal functional group having satisfactory adsorbability to silver surface. Examples thereof include compounds having a hydroxyl group, a carboxyl group, an amino group, a thiol group, and a disulfide group. Furthermore, in order to prevent reoxidation of the silver particles or adsorption and contamination of excess organic materials, it is preferable that the main structure of the compound have a linear alkane structure which allows dense filling of the protective material. It is more preferable that the alkane structure has 4 or more carbon atoms so that the carbon chains may be densely filled by an intermolecular force. Furthermore, in order for the silver particles to be sintered at a low temperature of 200° C. or lower, it is more preferable that the alkane structure have 18 or fewer carbon atoms so that the detachment temperature of the surface protective material from the silver surface is lower than 200° C.

In regard to the concentration of the surface protective material in the acidic solution, when the total amount of the acidic solution is designated as 100 parts by weight, the concentration of the surface protective material is preferably 0.0001 parts by weight or greater in order to prevent aggregation between the silver particles, and is preferably 1 part by weight or less in order to prevent excessive physical adsorption of the surface protective material to the silver particles.

The proportion of the silver particles in the adhesive composition is preferably 80 parts by weight or greater relative to 100 parts by weight of the adhesive composition in order to increase thermal conductivity, and is more preferably 87 parts by weight or greater in order to achieve a thermal conductivity higher than or equal to that of high temperature solder. Furthermore, in order to prepare the adhesive composition in a paste form, the proportion of the silver particles is preferably 99 parts by weight or less, and in order to achieve an enhancement in workability with a dispenser or a printing machine, the proportion is more preferably 95 parts by weight or less.

The alcohol or carboxylic acid having a boiling point of 300° C. or higher that is used in the present invention is not particularly limited as long as the alcohol or carboxylic acid does not interfere with sintering of the silver particles.

Examples of the alcohol or carboxylic acid having a boiling point of 300° C. or higher include aliphatic carboxylic acids such as palmitic acid, stearic acid, arachidic acid, terephthalic acid, and oleic acid; aromatic carboxylic acids such as pyromellitic acid and o-phenoxybenzoic acid; aliphatic alcohols such as cetyl alcohol, stearyl alcohol, isobornylcyclohexanol, and tetraethylene glycol; and aromatic alcohols such as p-phenylphenol. Among them, those alcohols and carboxylic acids whose melting point is lower than the temperature at which a thermal history is applied are preferred. This is because since liquids have superior wettability to the object to be adhered and the silver particles and superior reactivity at the time of heating as compared with solids, the adhesive force to the object to be adhered can be increased. Among them, in particular, an aliphatic alcohol or carboxylic acid having 6 to 20 carbon atoms is more preferred. It is because an adhesive composition comprising such a carboxylic acid or alcohol exhibits satisfactory sinterability of the silver particles, and also, the coating workability of the adhesive composition with a dispenser or a printing machine is excellent due to an enhancement of dispersibility as well as prevention of sedimentation of the silver particles.

With regard to the alcohol or carboxylic acid having a boiling point of 300° C. or higher, one kind or optionally a mixture of two or more kinds of such components can be used. When the amount of the volatile component is designated as 100 parts by weight, the amount of the alcohol or carboxylic acid having a boiling point of 300° C. or higher is preferably 1 part by weight to 100 parts by weight. If the amount of the alcohol or carboxylic acid having a boiling point of 300° C. or higher is greater than 100 parts by weight, when a predetermined thermal history is applied, residual component may inhibit aggregation or sintering of silver, and as compactness is impaired, there is a risk that the electrical conductibility, thermal conductibility or adhesive force may be impaired. If the amount is less than 1 part by weight, there is a risk that a sufficient promoting effect for the sintering of the silver particles may not be obtained, and the adhesive force may be decreased.

The adhesive composition of the present invention may further comprise a volatile component. There are no particular limitations on the volatile component as long as it has a boiling point of 100° C. to 300° C., and when a mixture of silver particles with the volatile component is subjected to a predetermined thermal history, the silver particles can be sintered.

Examples of such a volatile component include monohydric and polyhydric alcohols such as pentanol, hexanol, heptanol, octanol, decanol, ethylene glycol, diethylene glycol, propylene glycol, butylene glycol, and α-terpineol; ethers such as ethylene glycol butyl ether, ethylene glycol phenyl ether, diethylene glycol methyl ether, diethylene glycol ethyl ether, diethylene glycol butyl ether, diethylene glycol isobutyl ether, diethylene glycol hexyl ether, triethylene glycol methyl ether, diethylene glycol dimethyl ether, diethylene glycol diethyl ether, diethylene glycol dibutyl ether, diethylene glycol butyl methyl ether, diethylene glycol isopropyl methyl ether, triethylene glycol dimethyl ether, triethylene glycol butyl methyl ether, propylene glycol propyl ether, dipropylene glycol methyl ether, dipropylene glycol ethyl ether, dipropylene glycol propyl ether, dipropylene glycol butyl ether, dipropylene glycol dimethyl ether, tripropylene glycol methyl ether, and tripropylene glycol dimethyl ether; esters such as ethylene glycol ethyl ether acetate, ethylene glycol butyl ether acetate, diethylene glycol ethyl ether acetate, diethylene glycol butyl ether acetate, dipropylene glycol methyl ether acetate, ethyl lactate, butyl lactate, and γ-butyrolactone; acid amides such as N-methyl-2-pyrrolidone, N,N-dimethylacetamide, and N,N-dimethylformamide; aliphatic hydrocarbons such as cyclohexanone, octane, nonane, decane, and undecane; and aromatic hydrocarbons such as benzene, toluene, and xylene, and appropriate mercaptans include mercaptans containing 1 to 18 carbon atoms, such as ethyl-, n-propyl-, i-propyl-, n-butyl-, i-butyl-, t-butyl-, pentyl-, hexyl- and dodecylmercaptans, and cycloalkylmercaptans containing 5 to 7 carbon atoms, such as cyclopentyl-, cyclohexyl- and cycloheptylmercaptans. Among them, volatile components having a boiling point of 150° C. or higher are preferred. It is preferable that an adhesive composition comprising a volatile component having a boiling point of 150° C. or higher exhibits a very small increase of viscosity, and has excellent work stability at the time of semiconductor device production. Among them, in particular, alcohols having 4 to 12 carbon atoms, esters, and ethers are more preferred. It is because such a volatile component has excellent dispersibility of silver particles that have been subjected to the removal of oxide film and a surface treatment.

The volatile component to be included can be used singly, or as mixtures of two or more components as necessary. For an enhancement of thermal conductibility, the content is preferably 20 parts by weight or less relative to 100 parts by weight of the adhesive composition.

The adhesive composition of the present invention may comprise one or more of a diluent, a wettability enhancing agent and a defoamant for enhancing workability. Meanwhile, the adhesive composition of the present invention may also comprise components other than those listed herein.

In the adhesive composition of the present invention, if necessary, a hygroscopic agent such as calcium oxide or magnesium oxide; an adhesive force enhancing agent such as a silane coupling agent, a titanate coupling agent, an aluminum coupling agent, or a zircoaluminate coupling agent; a wettability enhancing agent such as a nonionic surfactant or a fluorine-based surfactant; a defoamant such as a silicone oil; and an ion trapping agent such as an inorganic ion exchanger can be appropriately included.

Here, examples of the silane coupling agent include vinyltris(β-methoxyethoxy)silane, vinyltriethoxysilane, vinyltrimethoxysilane, γ-methacryloxypropyltrimethoxysilane, β-(3,4-epoxycyclohexyl)ethyltrimethoxysilane, γ-glycidoxypropyltrimethoxysilane, γ-glycidoxypropylmethyldiethoxysilane, N-phenyl-γ-aminopropyltrimethoxysilane, γ-mercaptopropyltrimethoxysilane, hexamethyldisilazane, N,O-(bistrimethylsilyl)acetamide, N-methyl-3-aminopropyltrimethoxysilane, 4,5-dihydroimidazole propyltriethoxysilane, γ-mercaptopropyltriethoxysilane, γ-mercaptopropylmethyldimethoxysilane, 3-cyanopropyltrimethoxysialne, methyltri(methacryloyloxyethoxy)silane, methyltri(glycidyloxy)silane, 2-ethylhexyl-2-ethylhexyl phosphonate, γ-glycidoxypropylmethyldimethoxysilane, vinyltriacetoxysilane, γ-anilinopropyltrimethoxysilane, γ-mercaptopropylmethyldimethoxysilane, γ-methacryloxypropylmethyldimethoxysilane, N-trimethylsilylacetamide, dimethyltrimethylsilylamine, diethyltrimethylsilylamine, trimethylsilylimidazole, trimethylsilyl isocyanate, dimethylsilyl diisocyanate, methylsilyl triisocyanate, vinylsilyl triisocyanate, phenylsilyl triisocyanate, tetraisocyanatosilane, and ethoxysilane triisocyanate.

Examples of the titanate coupling agent include isopropyltriisostearoyl titanate, isopropyltrioctanoyl titanate, isopropyldimethacrylisostearoyl titanate, isopropyltridodecylbenzenesulfonyl titanate, isopropylisostearoyldiacryl titanate, isopropyl tri(dioctyl phosphate) titanate, isopropyltricumylphenyl titanate, isopropyl tris(dioctyl pyrophosphate) titanate, tetraisopropyl bis(dioctyl phosphite) titanate, tetraoctyl bis(ditridecyl phosphite) titanate, tetra(2,2-diallyloxymethyl-1-butyl)bis(ditridecyl)phosphite titanate, dicumylphenyloxyacetate tianate, bis(dioctyl pyrophosphate) oxyacetate titanate, diisostearoylethylene titanate, bis(dioctyl pyrophosphate)ethylene titanate, diisopropoxybis(2,4-pentadionato)titanium (IV), diisopropyl bistriethanolaminotitanate, titanium lactate, acetoacetic ester titanate, di-i-propoxybis(acetylacetonato)titanium, di-n-butoxybis(triethanolaminato)titanium, dihydroxybis(lactato)titanium, titanium-i-propoxyoctylene glycolate, titanium stearate, tri-n-butoxytitanium monostearate, titanium lactate ethyl ester, and titanium triethanol aminate.

In the adhesive composition of the present invention, a bleed suppressing agent may be further included as necessary. Examples of the bleed suppressing agent include fatty acids such as perfluorooctanoic acid, octanoic acid amide, and oleic acid; perfluorooctyl ethyl acrylate, and silicone.

In order to prepare an adhesive composition of the present invention, silver particles, and an alcohol or carboxylic acid having a boiling point of 300° C. or higher, may be subjected, together with a volatile component and/or various additives that are added if necessary, to mixing, dissolving, degranulating kneading, or dispersing, under heating as necessary, all at once or in divided portions, by appropriately combining dispersion/dissolution apparatuses such as a stirrer, a Raikai mixer, a three-roll mill and a planetary mixer, to obtain a uniform paste.

The semiconductor device of the present invention is obtained by adhering a semiconductor element to a supporting member by using the adhesive composition of the present invention. After the semiconductor element is adhered to the supporting member, a wire bonding process and an encapsulation process are carried out according to necessity. Examples of the supporting member include lead frames such as a 42 alloy lead frame, a copper lead frame, and a palladium PPF lead frame; and organic substrates such as a glass epoxy substrate (a substrate formed from a glass fiber-reinforced epoxy resin), and a BT substrate (a substrate using a BT resin formed from a cyanate monomer or an oligomer thereof and bismaleimide).

In order to adhere a semiconductor element to a supporting member such as a lead frame by using the adhesive composition of the present invention, first, the adhesive composition is applied on the supporting member by a dispensing method, a screen printing method, a stamping method or the like, and then the semiconductor element is mounted thereon. Subsequently, the assembly is subjected to heating and curing by using a heating apparatus such as an oven or a reflow. Heating and curing is usually carried out by heating at 100° C. to 200° C. for 5 seconds to 10 hours. Furthermore, the assembly is subjected to a wire bonding process, and then is encapsulated by a conventional method. Thereby, a semiconductor device is completed.

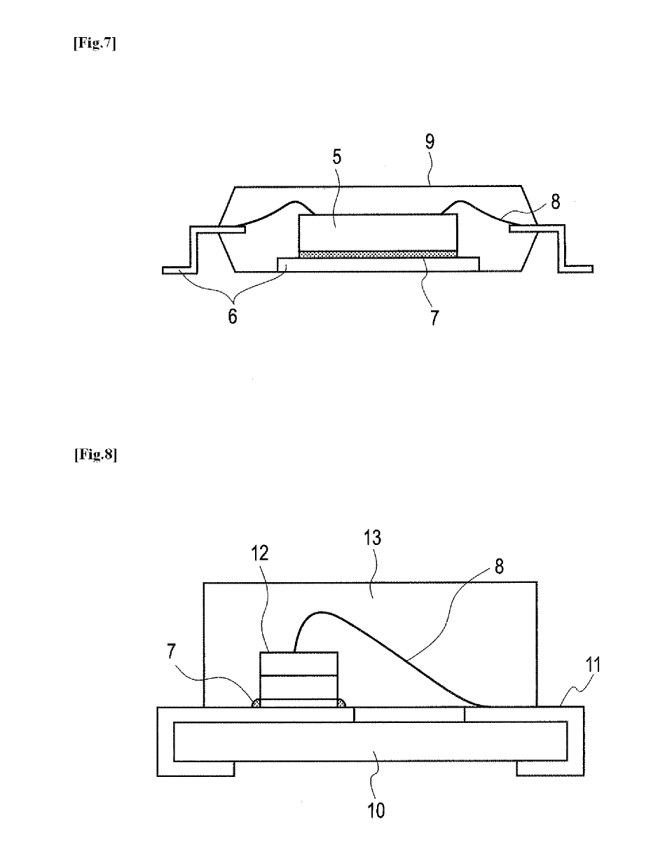

FIG. 7 illustrates an example of a semiconductor device using the adhesive composition of the present invention. A chip 5 and a lead frame 6 are fixed by an adhesive layer 7 formed from the adhesive composition of the present invention, and the chip 5 and the lead frame 6 are electrically connected by a wire 8. The entirety is encapsulated by a molding resin 9.

FIG. 8 illustrates another example of the semiconductor device using the adhesive composition of the present invention. An electrode 11 and an LED chip 12 formed on a substrate 10 are fixed by an adhesive layer 7 formed from the adhesive composition of the present invention and are also electrically connected by a wire 8, and the assembly is molded by a translucent resin 13.

### EXAMPLES

Next, the present invention will be described in detail by way of Examples, but the present invention is not intended to be limited to these. Those materials used in Examples and Reference Examples are materials produced as follows, or materials purchased.

(1) Alcohol or carboxylic acid having a boiling point of 300° C. or higher: Stearic acid (boiling point: 376° C., Wako Pure Chemical Industries, Ltd.), tetraethylene glycol (boiling point: 327° C., hereinafter abbreviated to TEG, Wako Pure Chemical Industries, Ltd.), and isobornylcyclohexanol (boiling point: 308° C., hereinafter, abbreviated to MTPH)

(2) Volatile component: Dipropylene glycol dimethyl ether (boiling point: 175° C., hereinafter, abbreviated to DMM, Daicel Chemical Industries, Ltd.), γ-butyrolactone (boiling point: 204° C., hereinafter, abbreviated to GBL, Sankyo Chemical Industries, Ltd.), triethylene glycol butyl methyl ether (boiling point: 261° C., hereinafter, abbreviated to BTM, Toho Chemical Industry Co., Ltd.), and diethylene glycol monobutyl ether (boiling point: 231° C., hereinafter, abbreviated to BDG, Daicel Chemical Industries, Ltd.)

(3) Silver particles: AgF10S (Tokuriki Chemical Research Co., Ltd., trade name, silver powder, average particle size: 10 μm, oxygen state ratio: 15%), AgF5S (Tokuriki Chemical Research Co., Ltd., trade name, silver powder, average particle size: 5 μm, oxygen state ratio: 20%)

(4) Surface treated silver particles:

28 parts by weight of hydrochloric acid (Kanto Chemical Co., Inc.) was diluted with ethanol (Kanto Chemical Co., Inc.), and thus 80 parts by weight of an acidic solution was prepared. To this acidic solution, 0.29 parts by weight of stearylmercaptan (Tokyo Chemical Industry Co., Ltd.) as a surface protective material was added, and thus a surface treating liquid was prepared. To this surface treating liquid, 20 parts by weight of AgF10S or AgF5S described above was added, and the mixture was stirred for one hour while maintained at 40° C. Thus, removal of oxide film and a surface treatment were carried out. Thereafter, the surface treating liquid was removed by filtration, and ethanol at 40° C. was added to the residue to wash the surface treated silver powder. Furthermore, the ethanol washing liquid was removed by filtration, and the processes of washing and filtration were repeated about 10 times. Thereby, the stearylmercaptan and hydrochloric acid that were physically adsorbed on the surface of the surface treated silver powder were removed. The surface treated silver powder obtained after the final washing was dried under reduced pressure to remove ethanol, and thus a surface treated silver powder in a dried state was obtained. The oxygen state ratio of the surface treated silver powder thus obtained was 0% for AgF10S, and 5% for AgF5S, and it was confirmed that oxide film had been removed.

### Examples 1 to 8 and Reference Examples 1 to 5

Materials (1) and (2) were kneaded at the mixing proportions indicated in Table 1 or Table 2 for 10 minutes with a Raikai mixer, and thus a liquid component was obtained. Furthermore, surface treated or untreated silver particles (3) or (4) were kneaded with the liquid component for 15 minutes with a Raikai mixer, and thus an adhesive composition was obtained.

The characteristics of the adhesive composition were investigated by a method such as described below, and the analysis results are presented in Table 1 and Table 2.

(1) Die shear strength: The adhesive composition was applied in an amount of about 0.2 mg on an Ag-plated Cu lead frame (land area: 10×5 mm), and an Au-plated Si chip (Au plating thickness: 200 nm, chip thickness: 0.4 mm) having a size of 2 mm×2 mm was adhered thereon. This assembly was heat-treated at 180° C. for one hour in a clean oven (manufactured by Tabai Espec Corp., PVHC-210). This was heated for 30 seconds at 260° C., and then the shear strength (MPa) was measured using a versatile type bond tester (manufactured by Dage Corp., 4000 series) at a measurement speed of 500 μm/s and a measurement height of 100 μm.

(2) Thermal conductivity of adhesive composition cured product: The adhesive composition was heat-treated at 180° C. for one hour in a clean oven (manufactured by Tabai Espec Corp., PVHC-210), and thus a test specimen having a size of 10×10×1 mm was obtained. The thermal diffusivity of this test specimen was measured by a laser flash method (manufactured by Netzsch Group, LFA 447, 25° C.), and from the product of this thermal diffusivity, the specific heat capacity obtained with a differential scanning calorimeter (manufactured by Perkin Elmer, Inc., Pyris1), and the specific gravity obtained by the Archimedean method, the thermal conductivity (W/m·K) of the cured product of the adhesive composition at 25° C. was calculated.

(3) Volume resistivity: The adhesive composition was heat-treated at 180° C. for one hour in a clean oven (manufactured by Tabai Espec Corp., PVHC-210), and thus a test specimen having a size of 1×50×0.03 mm was obtained on a glass plate. The volume resistivity value of this test specimen was measured by a four-terminal method (manufactured by Advantest Corp., R687E Digital Multimeter).

TABLE 1

| | | | Example | | | | | | | |
|---|---|---|---|---|---|---|---|---|---|---|
| Item | | | 1 | 2 | 3 | 4 | 5 | 6 | 7 | 8 |
| Composition | Metal particles | Surface treated | 92 | 92 | 92 | 92 | 92 | 92 | 92 | — |
| | (State ratio of | AgF10S (0%) | | | | | | | | |
| | oxygen derived | Surface treated | — | — | — | — | — | — | — | 92 |
| | from oxidation) | AgF5S (5%) | | | | | | | | |
| | Volatile component | DMM | — | 4 | — | — | — | 7.8 | 4 | — |
| | | GBL | — | — | 4 | — | — | — | — | 4 |
| | | BTM | — | — | — | 4 | — | | — | |
| | | BDG | — | — | — | — | 4 | | — | |
| | Alcohol or | Stearic acid | — | — | — | — | — | 0.2 | — | — |
| | carboxylic acid | TEG | 8 | — | — | — | — | — | 4 | 4 |
| | having boiling | MTPH | — | 4 | 4 | 4 | 4 | — | — | — |
| | point of 300° C. | | | | | | | | | |
| | or higher | | | | | | | | | |

| | | | | | | | | | |
|---|---|---|---|---|---|---|---|---|---|
| Characteristics | Thermal conductivity (W/m · K) | 40 | 67 | 65 | 63 | 72 | 77 | 70 | 73 |
| | Volume resistivity (× 10⁻⁶ Ω · cm) | 9.6 | 6.5 | 7.1 | 8 | 6 | 6.3 | 6.2 | 5.8 |
| | Shear strength (MPa) | 10.6 | 16 | 15.5 | 15.1 | 17.6 | 17.9 | 16.7 | 17.2 |

TABLE 2

| | | | Reference Example | | | | |
|---|---|---|---|---|---|---|---|
| Item | | | 1 | 2 | 3 | 4 | 5 |
| Composition | Metal particles | Surface treated | — | — | — | 92 | 92 |
| | (State ratio of | AgF10S (0%) | | | | | |
| | oxygen derived | AgF10S (15%) | 92 | 92 | 92 | — | — |
| | from oxidation) | | | | | | |
| | Volatile | DMM | 7.8 | 4 | 4 | 8 | 4 |
| | component | | | | | | |
| | Alcohol or | Stearic acid | 0.2 | — | — | — | — |
| | carboxylic acid | TEG | — | 4 | — | — | — |
| | having boiling | MTPH | — | — | 4 | — | — |
| | point of 300° C. | | | | | | |
| | or higher | | | | | | |
| | Alcohol having | BDG | — | — | — | — | 4 |
| | boiling point of | | | | | | |
| | lower than 300° C. | | | | | | |

| | | | | | | |
|---|---|---|---|---|---|---|
| Characteristics | Thermal conductivity (W/m · K) | 0* | 0* | 0* | 76 | 78 |
| | Volume resistivity (× 10⁻⁶ Ω · cm) | 0* | 0* | 0* | 6.7 | 6.5 |
| | Shear strength (MPa) | 0 | 0 | 0 | 5.1 | 7.2 |

*Since the silver particles were not sintered, the test specimens for measuring the volume resistivity and thermal conductivity could not be produced.

From Example 1, it was found that when a composition comprising a silver powder having an oxygen state ratio of less than 15% (surface treated AgF10S) and an alcohol or carboxylic acid having a boiling point of 300° C. or higher, was heat-treated at 180° C. for one hour, a volume resistivity of 9.6×10⁻⁶ Ω·cm, a high thermal conductivity of 40 W/m·K, and a high shear strength of 10.6 MPa or greater at 260° C. were achieved, and the composition exhibited high electrical conductibility, high thermal conductibility (30 W/m·k), and high adhesiveness (10 MPa) that were equivalent or superior to Sn95Pb solder.

From Examples 2 to 8, it was found that when a composition comprising a silver powder having an oxygen state ratio of less than 15% (surface treated AgF10S or surface treated AgF5S), a volatile component, and an ethanol or a carboxylic acid having a boiling point of 300° C. or higher was heat-treated at 180° C. for one hour, a volume resistivity of 1.0×10⁻⁵ Ω·cm or less, a high thermal conductivity of 60 W/m·K, and a high shear strength of 14 MPa or higher at 260° C. were achieved.

From Reference Examples 1 to 3, in compositions comprising a silver powder having an oxygen state ratio of 15% (AgF10S), a volatile component, and an alcohol or carboxylic acid having a boiling point of 300° C. or higher, sintering between silver particles at 180° C. did not occur, test specimens for measuring volume resistivity and thermal conductivity could not be produced, and the test specimens were not connected with the object to be adhered.

From Reference Example 4, it was found that when a composition formed from a silver powder having an oxygen state ratio of less than 15% (surface treated AgF10S) and a volatile component was heat-treated at 180° C. for one hour, the composition exhibited a volume resistivity of 1.0×10⁻⁵ Ω·cm or less and a high thermal conductivity of 70 W/m·K or higher, but the adhesive force to an Au-plated area of the object to be adhered was very weak, and the shear strength was 5.1 MPa, while the adhesive force was inferior to that of Sn95Pb solder.

From Reference Example 5, it was found that when a composition comprising a silver powder having an oxygen state ratio of less than 15% (surface treated AgF10S), a volatile component, and an alcohol (BDG) having a boiling point of lower than 300° C. was heat-treated at 180° C. for one hour, the composition exhibited a volume resistivity of 1.0×10⁻⁵Ω·cm or less and a high thermal conductivity of 70 W/m·K (or higher, but the adhesive force to an Au-plated area of the object to be adhered was very weak, and the shear strength was 7.2 MPa, while the adhesive force was inferior to that of Sn95Pb solder. In this regard, it is speculated that since BDG volatilized before reacting with Ag particles, and could not form a sufficient adhesion phase with the Au interface, the shear strength decreased.

### Example 9

Semiconductor devices as illustrated in FIG. 7 were produced by using the adhesive compositions of Examples 1 to 8 obtained as described above. More specifically, each of the adhesive compositions of Examples 1 to 8 was applied on an Ag-plated Cu lead frame, and an Au-plated semiconductor element was mounted thereon. This assembly was heated at 180° C. for one hour in a clean oven, and thereby the semiconductor element was connected onto the lead frame. Thereafter, the assembly was subjected to a wire bonding process by using an Au wire, and then was encapsulated by a conventional method. Thus, semiconductor devices were produced.

Furthermore, semiconductor devices as illustrated in FIG. 8 were produced by using the adhesive compositions of Examples 1 to 8 obtained as described above. More specifically, each of the adhesive compositions of Examples 1 to 8 was applied on an Ag-plated Cu lead frame, and an Au-plated LED chip was mounted thereon. This assembly was heated at 180° C. for one hour in a clean oven, and thereby the LED chip was connected onto the lead frame. Thereafter, the assembly was subjected to a wire bonding process by using an Au wire, and then was encapsulated with a translucent resin by a conventional method. Thus, semiconductor devices were produced.

### REFERENCE NUMERAL LIST

1 SURFACE PROTECTIVE MATERIAL
2 OXIDE FILM
3 BULK METAL (UNOXIDIZED AREA OF SILVER)
4 PARTICULAR SURFACE PROTECTIVE MATERIAL ADSORBED BY SURFACE TREATMENT
5 CHIP (HEAT GENERATING BODY)
6 LEAD FRAME (HEAT DISSIPATING BODY)
7 ADHESIVE LAYER FORMED FROM CONNECTION MATERIAL OF INVENTION
8 WIRE
9 MOLDING RESIN
10 SUBSTRATE
11 ELECTRODE
12 LED CHIP (HEAT GENERATING BODY)
13 TRANSLUCENT RESIN

1. An adhesive composition comprising:
(A) silver particles having a state ratio of oxygen derived from silver oxide of less than 15% as measured by X-ray photoelectron spectroscopy; and
(B) an alcohol or carboxylic acid having a boiling point of 300° C. or higher.

2. The adhesive composition according to claim 1, further comprising:
(C) a volatile component having a boiling point of 100° C. to 300° C.

3. The adhesive composition according to claim 1, wherein the silver particles are obtained by subjecting to:
a treatment for removing oxide film until the silver particles have a state ratio of oxygen derived from silver oxide of less than 15% as measured by X-ray photoelectron spectroscopy, and
a surface treatment for preventing reoxidation and aggregation of the silver particles.

4. The adhesive composition according to claim 1, wherein an average particle size of the silver particles is from 0.1 μm to 50 μm.

5. The adhesive composition according to claim 1, wherein a volume resistivity is 1×10⁻⁴ Ωcm or less and a thermal conductivity is 30 W/m K or higher when the silver particles are sintered by applying a thermal history of from 100° C. to 200° C.

6. A semiconductor device having a structure in which a semiconductor element and a supporting member for mounting a semiconductor element are adhered by means of the adhesive composition according to claim 1.

7. A semiconductor device having a structure in which a semiconductor element and a supporting member for mounting a semiconductor element are adhered by means of the adhesive composition according to claim 2.
